(19) United States
(12) Patent Application Publication
(10) Pub. No.: US 2018/0119278 A1
(43) Pub. Date: May 3, 2018

(54) PECVD BOAT

(71) Applicant: KORNMEYER CARBON-GROUP GMBH, Windhagen (DE)

(72) Inventors: Torsten KORNMEYER, Konigswinter (DE); Hans-Peter VOLK, Griesingen (DE)

(73) Assignee: KORNMEYER CARBON-GROUP GMBH, Windhagen (DE)

(21) Appl. No.: 15/566,030

(22) PCT Filed: Apr. 13, 2016
(86) PCT No.: PCT/EP2016/058062

§ 371 Date: Oct. 12, 2017

(30) Foreign Application Priority Data
Apr. 13, 2015 (DE) 10 2015 105 599.6

(51) Int. Cl. C23C 16/458; C23C 16/50

(52) U.S. Cl. CPC C23C 16/4587; C23C 16/4581; C23C 16/50

(57) ABSTRACT

A PECVD boat has at least one boat plate for accommodating wafers, for transport into and out of vacuum coating chambers. The boat plate is oriented vertically and has a plurality of U-shaped accommodating slots for accommodating wafers, which slots are oriented in the longitudinal direction of the boat plate and are open at the top, in such a way that the wafers inserted into the accommodating slots are aligned with the plate line of the boat plate.

The invention relates to a PECVD boat having at least one boat plate for receiving wafers, for transport into and out of vacuum coating chambers.

PECVD boats are used for example in Plasma-Enhanced Chemical Vapor Deposition (PECVD). PECVD is a method for depositing thin films from the gas phase into a solid state on a substrate such as a wafer. The PECVD process is carried out in an evacuated vacuum chamber, in that as many wafers as possible, on what are termed plasma boats or PECVD boats consisting of individual boat plates, are introduced simultaneously into the vacuum chamber, and remain on these plasma boats during the PECVD process.

In order to be able to carry out a PECVD process, it is necessary that the wafers introduced with the PECVD boat(s), and the PECVD boats themselves, are heated to a predefined process temperature.

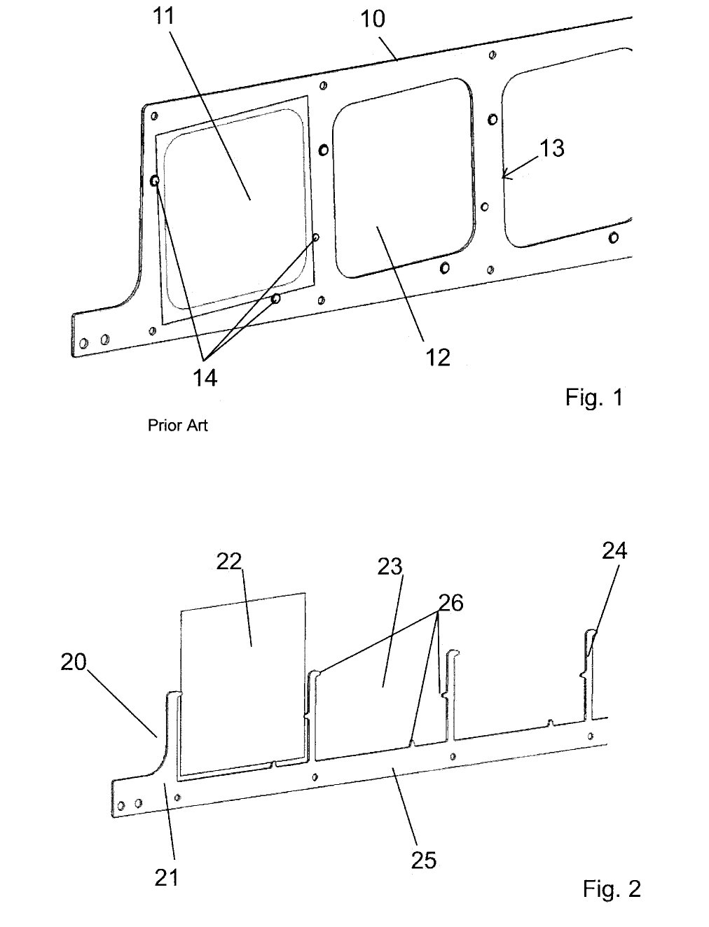

Commonly used PECVD boats, or the boat plates, are currently made of an electrically conductive material such as graphite or titanium. FIG. 1 (prior art) shows, in plain view, a boat plate 10 of a PECVD boat for receiving multiple rectangular or square wafers 11 in a lying arrangement according to the prior art. In order to securely hold a wafer 11 over each milled-out portion 12, three retaining pins 14 are provided on the rim 13 of the boat plate 10 surrounding the milled-out portion 12, so that the wafers 11 placed on the boat plate 10 cannot slip during transport.

In the interests of maximum wafer capacity, it is common for multiple such boat plates 10 to be connected together stacked one atop the other using appropriate spacers, to form a PECVD boat with greater wafer capacity.

The PECVD boats satisfy on one hand the requirement of securely holding the wafers 11 during transport and during the deposition process, and on the other hand it is necessary for an electrical potential that is required for the deposition process to be applied to the wafers via the PECVD boat, or the boat plates.

The wafers 11 rest on or are suspended from the boat plate 10, wherein the necessary electrical contact is additionally established by the retaining pins 14 on the boat plate 10 which is for example made of graphite.

In order to reduce the thermal mass, the boat plates 10 are provided with milled-out portions 12 or openings that are smaller than the wafers 11, so that each wafer 11 bears against a frame-shaped region of the boat plate that in each case surrounds an opening. Thus, the wafer rim always has peripheral thermal and electrical contact with the frame of the boat plate 10.

The time required for heating up is determined in particular by the number of wafers to be heated up, the mass of the PECVD boat, the homogenization time required to reach an even temperature distribution, and the manner in which heating is carried out. It is obvious that, in the interests of an effective and rapid deposition process, both the heating-up time and the subsequent homogenization time should be as short as possible.

The wafer temperature is influenced or determined essentially by the temperature of the graphite plate, wherein the mass of the boat plates currently in use represents 4 to 5 times the mass of the wafers.

In some process steps, it is only possible to heat the PECVD boat by convection and/or heat radiation—without auxiliary plasma support. This results in long heating phases and therefore a loss of machine capacity and throughput. Furthermore, the relatively high mass of the PECVD boat that generally contains many boat plates leads to high thermal inertia.

This results in excessive heating/cooling and stabilization times (homogenization times) until the wafers have either been heated to the desired process temperature, or have cooled down again after the PECVD process.

The invention is based on the object of providing a low-mass PECVD boat for receiving wafers and for transport into and out of vacuum chambers, which provides an increase in the throughput of the machine by virtue of greater wafer capacity and shortened process cycles as well as an energy saving in the heating and homogenization phase.

The object upon which the invention is based is achieved with the features of the main claim, in that the boat plate is oriented vertically and is provided with multiple U-shaped receiving slots, that are oriented in the longitudinal direction of the boat plate and are open at the top, for receiving wafers, such that the wafers inserted into the receiving slots are flush with the plate line of the boat plate.

Further advantageous embodiments form the subject matter of the associated dependent claims.

Thus, each receiving slot is bounded by lateral retaining arms and a lower frame element of the boat plate, so that the wafer inserted into the receiving slot is partially surrounded by the lateral retaining arms.

In order to keep thermal conductivity to a minimum, three receiving elements are provided in each receiving slot, the lateral retaining arms and the lower frame element each being provided with one receiving element, which receiving elements are oriented inward into the receiving slot and grip around the outer edge of the inserted wafer in a U-shaped, V-shaped or fork-like manner and secure the wafer after insertion into the three receiving elements using just the weight of the wafer.

In the interests of a higher wafer capacity and to avoid deposition on the rear side of the wafer, two wafers can be inserted into the receiving elements of each receiving slot, in the form of a back-to-back loading.

Further, it is advantageous if multiple boat plates are arranged parallel, spaced apart from and next to one another and are connected to one another to form a PECVD boat, wherein spacing and connecting elements are located between the boat plates.

The spacing and connecting elements are made of a nonconductive material such as Al₂O₃, quartz glass or ceramic.

Furthermore, the boat plates are made of graphite, CFC or titanium and are produced by shaping processing methods.

The particular advantages of the boat plate according to the invention, or of the PECVD boat, lie in a smaller thermal mass, resulting in more rapid heating/cooling and homogenization of the PECVD boat fitted with wafers.

Further advantages are more wafers in the boat—that is to say increased production capacity and the plate thickness is used and no longer represents a waste of space since the wafers are in the plate line.

Also, the throughput of the machine is increased by greater wafer capacity and shortened process cycles as a consequence of the more rapid heating-up processes and, as a consequence, energy is saved in the heating-up/homogenization phase also by virtue of the reduced boat mass, resulting in a reduction in the heating energy.

Finally, energy is also saved in the cooling and discharge phase as a consequence of the reduced boat mass and the reduced cooling requirement resulting therefrom.

There follows a more detailed explanation of the invention by way of an exemplary embodiment. In the appended drawings:

FIG. 1 shows a boat plate according to the prior art for receiving wafers in the lying-down position;

FIG. 2 shows a boat plate according to the invention in an upright arrangement for receiving wafers;

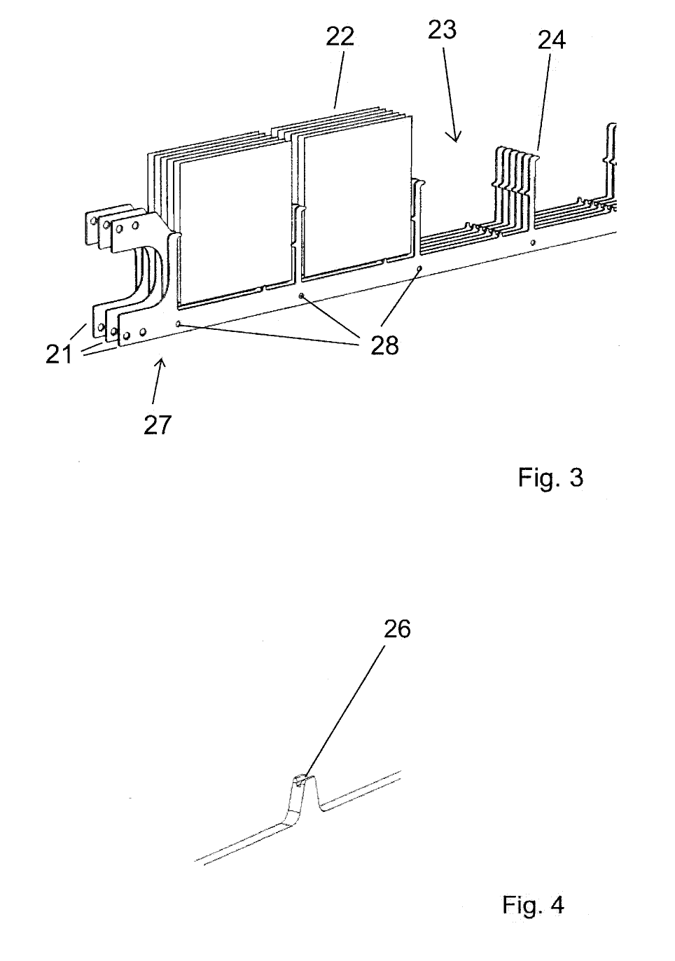

FIG. 3 shows a PECVD boat consisting of multiple boat plates arranged parallel, spaced apart from and next to one another and connected to one another; and

FIG. 4 shows an enlarged view of a receiving element for wafers.

FIG. 2 shows a wafer holder 20 according to the invention, which in this case consists of a boat plate 21 which is oriented vertically or on edge and serves to receive multiple wafers 22. In the case shown, it is intended to receive at most three wafers 22. To securely receive the wafers 22, there are provided in the boat plate 21 three receiving slots 23 that are arranged one behind the other in the longitudinal direction of the boat plate 21 and are bounded laterally by retaining arms 24 and by a lower frame element 25 of the boat plate 21. The length of the retaining arms 24 is dimensioned such that they reach only up to about half the height of the inserted wafers.

To securely receive the wafers 22, receiving elements 26 that are oriented inward into the receiving slot 23 project from the retaining arms 24 and the lower frame element 25. A groove, into which the outer edge of the wafer can engage, is worked into that end face of each of the receiving elements 26 that projects into the receiving slot 23. Thus, the receiving elements 26 grip slightly around the respective outer edge of the wafer 22 in a U-shaped, V-shaped or fork-like form-fitting manner and thus secure the wafers 22 after insertion into the receiving elements 26 such that these, after insertion into the receiving elements 26, are held securely (FIG. 4). It is also possible for two wafers 22 to be simultaneously received in each receiving slot 23, making it possible to avoid deposition on the rear side of the wafer.

The boat plate 21 is produced from one piece by shaping processing methods, for example milling. It is clear that the thickness of the boat plate 21 must be greater than the thickness of two back-to-back wafers inserted into the receiving elements 26.

To securely receive the wafers 22, it is sufficient to have in each receiving slot 23 three such receiving elements 26, specifically as shown in FIG. 2 at the upper end of the respective left-hand retaining arm 24, approximately in the middle of the respective right-hand retaining arm 24 and in the respective right-hand third of the lower frame element 25. The exact position of these receiving elements 26 is not important, but it is essential, in order to securely receive the wafers 22 in the receiving slot 23, that three such receiving elements 26 be present.

In this manner, each vertically oriented wafer 22 is securely fixed three-dimensionally at three points and by means of its own weight, and flush with the boat plate 21, such that the wafers 22 cannot fall out in the event of movement of the boat plate 21 in an essentially vertical use position of the boat plate 21.

FIG. 3 shows a wafer boat or PECVD boat 27 that consists of a multiplicity of vertically oriented boat plates 21 arranged spaced apart from and next to one another and mechanically connected to one another. For the mechanical connection between the boat plates 21, there are provided bores 28 for receiving spacing and connecting elements (not shown) that are made of a nonconductive material such as Al₂O₃, quartz glass or ceramic in order to avoid short-circuits.

The boat plates 21 can be made of graphite, CFC or titanium and can easily be produced using known shaping processing methods.

The PECVD boat 27 according to the invention can also be used to carry out a rear-side coating using a back-to-back loading of the wafers 22, by placing or inserting two wafers 22 into each of the receiving slots 23 of each boat plate 21, with their respective rear sides in contact with one another.

By virtue of the fact that the wafers 22 are each held in the boat plates 21 at just three points, they are largely free at a defined distance from the receiving slot 23. This has the particular advantage that the wafers 22 are, to the greatest possible degree, thermally decoupled from the boat plate 21 or the PECVD boat 27. Thus, the heating power can reach the wafer 22 much better without first having to heat up the mass of the boat plate 21. This leads to a marked shortening of the heating-up and cooling-down processes and of the homogenization time.

By virtue of the inventive configuration of the boat plates 21, the mass-to-surface-area ratio has changed greatly in favor of the wafers 22. Compared to their mass, the wafers 22 have a much greater surface area than the boat plate 21.

The boat plates 21, or the PECVD boats 27 composed thereof, according to the invention can be used in a great many PECVD processes and are well suited especially to processes, in the field of photovoltaics, in which TMA, SiNOx and SiN layers are deposited.

The boat plates 21 according to the invention can easily be produced, in one piece including the receiving elements 26, from graphite, CFC (Carbon Fiber-reinforced Carbon) or titanium by shaping processing methods. The thickness of the boat plates 21 must be greater than the thickness of the wafers 22 that are to be inserted into the receiving elements 26.

### LIST OF REFERENCE SIGNS

10 Boat plate
11 Wafer
12 Milled-out portion
13 Rim
14 Retaining pin
20 Wafer holder
21 Boat plate
22 Wafer
23 Receiving slot
24 Retaining arm
25 Lower frame element
26 Receiving element
27 PECVD boat
28 Bore

1. A PECVD boat having at least one boat plate for receiving wafers, for transport into and out of vacuum coating chambers, wherein the boat plate is oriented vertically and has multiple U-shaped receiving slots oriented in a longitudinal direction of the boat plate and open at a top, for receiving wafers, such that the wafers inserted into the receiving slots are flush with a plate line of the boat plate.

2. The PECVD boat as claimed in claim 1, wherein each receiving slot is bounded by lateral retaining arms and a lower frame element of the boat plate, so that a wafer inserted into the receiving slot is partially surrounded by the lateral retaining arms.

3. The PECVD boat as claimed in claim 2, further including three receiving elements, wherein the lateral retaining arms and the lower frame element are each provided with one of the receiving elements, and the receiving elements are oriented inward into the receiving slot and grip around an outer edge of the inserted wafer in a U-shaped or fork-like manner and secure the wafer using just weight of the wafer.

4. The PECVD boat as claimed in claim 3, wherein the receiving elements of each receiving slot accommodates two wafers in back-to-back loading.

5. The PECVD boat as claimed in claim 1, including multiple boat plates arranged parallel, spaced apart from and next to one another, and connected to one another.

6. The PECVD boat as claimed in claim 5, further comprising spacing and connecting elements, made of a nonconductive material, located between the boat plates.

7. The PECVD boat as claimed in claim 6, wherein the spacing or connecting elements are made of Al₂O₃, quartz glass or ceramic.

8. The PECVD boat as claimed in claim 5, wherein the boat plates comprise shaped graphite, CFC or titanium.
